(19) United States
(12) Patent Application Publication
(10) Pub. No.: US 2024/0363304 A1
(43) Pub. Date: Oct. 31, 2024

(54) IN-VACUUM CHAMBER CONTROLLED-GAS-FILM DEVICE TO REDUCE LASER ABLATION REDEPOSITS

(71) Applicant: FEI Company, Hillsboro, OR (US)

(72) Inventors: Jaroslav Velcovský, Brno (CZ); Remco T. J. P. Geurts, Eindhoven (NL); Marek Melichar, Hillsboro, OR (US)

(73) Assignee: FEI Company, Hillsboro, OR (US)

(21) Appl. No.: 18/509,205

(22) Filed: Nov. 14, 2023

Related U.S. Application Data
(60) Provisional application No. 63/498,227, filed on Apr. 25, 2023.

(51) Int. Cl. H01J 37/10; H01J 37/04; H01J 37/22; H01J 37/305

(52) U.S. Cl. CPC H01J 37/10; H01J 37/045; H01J 37/22; H01J 37/3053; H01J 2237/006

(57) ABSTRACT

Surface contamination and debris deposition associated with laser ablation or ion beam milling is reduced by combining a directed flow to a workpiece with suction at a suitable vacuum pressure. The vacuum pressure is typically selected so that any contaminants or debris have relatively short mean free paths to avoid build-up on distant surfaces in a vacuum chamber. A shutter can be used to shield portions of a charged-particle-beam optical column during processing. Processing at vacuum pressures associated with the relatively short MFPs can be combined with processing at vacuum pressures associated with relatively long MFPs to provide coarse and fine milling or ablation.

### CROSS REFERENCE TO RELATED APPLICATION

This application claims the benefit of U.S. Provisional Application No. 63/498,227, filed on Apr. 25, 2023, which is incorporated herein by reference in its entirety.

### FIELD

The disclosure pertains to vacuum processing.

### BACKGROUND

In many applications, milling or ablation processes are applied to workpieces situated in a vacuum chamber. During these processes, material removed from the workpiece can contaminate surfaces of components situated in the vacuum chamber. These surfaces include optical window surfaces such as surfaces of cover slips through which laser beams are directed, surfaces of shutters used to shield charged particle beam (CPB) optics, and surfaces of the workpiece itself. Reducing contamination such as material redeposition in ion beam and laser beam processing of workpieces situated in a vacuum is needed to improve processing throughput and avoid the need to replace parts such as optical windows due to contamination as discussed in U.S. Patent Application Publication 2022/0305584, which is incorporated herein by reference. Alternative approaches are needed, particularly approaches that allow a workpiece to remain situated for processing and imaging in the same vacuum chamber.

### SUMMARY

The disclosure pertains to processing methods, apparatus, and systems in which a gas flow can be directed to a workpiece from a flow tube and a suction tube used to extract portions of the directed gas flow and contaminants produced by workpiece processing. The workpiece can be situated in a vacuum chamber with different pressures selected to control the deposition of contaminants or processing debris at various locations in the vacuum chamber. In one example, high vacuum can be used for fine processing (and SEM imaging) and a low vacuum used for coarse or rapid processing. The workpiece can remain situated in the vacuum chamber as pressures, directed gas flows, suction, and processing beam characteristics are varied and the workpiece need not be removed to separate chamber for processing at low vacuum. Low vacuum with directed gas flow and suction reduces debris at the workpiece and nearby surfaces and permits rapid processing.

### BRIEF DESCRIPTION OF THE DRAWINGS

FIG. 1 illustrates a representative system that is operable to control contamination by directing a gas flow to a workpiece and applying suction to remove contamination from the workpiece.

FIG. 1A illustrates a representative arrangement of a gas delivery tube and a suction tube with respect to a pole piece of an objective lens.

FIGS. 1B-1C illustrate alternative locations for gas delivery and suction tubes.

FIG. 2 illustrates a representative method of processing a workpiece to reduce contamination.

FIG. 3 illustrates a representative system operable to image and process a workpiece to reduce contamination.

FIG. 4 illustrates a representative method of combined fine and coarse processing.

FIG. 5 illustrates a representative arrangement for control of gas flow, suction, and vacuum chamber pressure to implement processing such as ion beam milling or laser ablation with reduced contamination.

FIG. 6 illustrates a representative control system for use with any of the disclosed methods, systems, and apparatus.

### DETAILED DESCRIPTION

Contamination produced by milling and/or ablation processes in a vacuum chamber can affect multiple components of systems used for processing and imaging as well as the workpiece being processed. For example, material can be redeposited on the workpiece, on an optical window such a coverslip or other optical element through which an ablation optical beam is delivered to the workpiece, or a shutter situated to shield CPB imaging components (such as electron lenses) from redeposition. Other surfaces can also receive redeposited material, but these three examples can be used for convenient illustration. At pressures associated with low vacuum, ablated materials or other contaminants have relatively short mean free paths and tend to redeposit at a workpiece surface and nearby surfaces such as at a shutter used to protect the CPB optics while the optical window is too distant to receive appreciable contamination. At pressures associated with high vacuum, ablated materials or other contaminants have long mean free paths and tend to redeposit throughout the vacuum chamber such as at the shutter and the optical window while the workpiece receives little contamination.

The disclosed methods and apparatus permit local control of processing areas by providing a carrier gas to a workpiece surface area at suitable pressures, with the workpiece situated in a chamber. Local, controllable pressures and local gas flows offer advantages in a variety of situations. For example, a carrier gas can be directed to a selected area of a workpiece surface in situ to control redeposition of processing debris and associated surface contamination. In some cases, reactive gases such as fluorine or oxygen are used to reduce deposits. In one example, laser ablation processing can be performed with a carrier gas at the workpiece surface being processed and a processing rate can be regulated. Processing rates can be increased and performed at higher temperatures than without the local application of a carrier gas due to the contamination control provided. Processes using a carrier gas combined with a precursor such as an organic or halogenic compound that is supplied locally to a workpiece surface at a relatively high local pressure permits localized coating and/or deposition by, for example, precursor decomposition. In other examples, etching processes can be localized based on the local gas delivery. Such processes can be performed in situ, without moving the workpiece into a second chamber. The local delivery of carrier gas (with precursors or other gases) whether for material removal or etching combined with local removal of the carrier gas and debris limits the exposure of other surfaces in the chamber and chamber walls.

As shown in the table below, contamination can be controlled by suitable selection of vacuum chamber pressure and directing gas flows to the workpiece and removal of contaminants at the workpiece by suction. In the table, L refers to low contamination, LL refers to lowest contamination, H refers to high contamination, HH refers to highest contamination, and M refers to moderate contamination. Pressures associated with low vacuum are indicated as LV, and pressures associated with high vacuum are indicated as HV. At LV use of both directed gas flow and suction tends to reduce shutter and workpiece contamination. This arrangement is preferred for high volume milling or ablation processes that generate relatively large amounts of contaminants. As noted in the table, this arrangement produces some workpiece contamination and better milling or ablation results can be obtained at pressures associated with HV. Since processing at HV tends to contaminate the optical window (and other surfaces in the vacuum chamber), HV processing can be used for final or fine processing without directed gas flow or suction and bulk or coarse processing done at LV with directed gas flow and suction.

Milling/Ablation Characteristics

| | Contamination | | | Milling | |
|---|---|---|---|---|---|
| Chamber | shutter | coverslip | workpiece | Quality | Typical Use |
| high vac. | M | HH | LL | best | fine, precise |
| (HV) | | | | | milling |
| low vac. | H | none | HH | worst | generally not |
| (LV) | | | | | preferred |
| LV suction | HH | none | M | moderate | good high- |
| | | | | | volume |
| | | | | | milling |
| LV suction | L | none | L | good | better high- |
| and flow | | | | | volume |
| | | | | | milling |

The disclosed approaches can reduce laser ablation redeposits/debris in a vacuum chamber that can contaminate a laser objective coverslip, a laser chamber shutter, electron and ion beam detectors, other internal components, and a surface or a workpiece being processed. Thus, lifetimes of laser components (laser objective coverslip, laser chamber shutter) and electron optical components can be extended and a frequency at which coverslips must be exchanged reduced, resulting in higher material processing throughput and reduced cost of ownership (for example, maintenance and consumables). With reduced coverslip contamination, preventive maintenance can be less frequent and laser power tends not to decline during and as a result of workpiece processing. Typical applications include large volume material removal in chamber by lasers for semiconductors (logic, memory, packaged devices), materials research (metals, ceramics, polymers, batteries, etc.), and life sciences (soft materials). Refractive materials (metals) are associated with high rates of contamination and contamination produced by processing with such materials is one application of the disclosed approaches. Local gas flow at suitable pressures can provide satisfactory deposition rates while simultaneously limiting contamination throughout a processing chamber containing the workpiece. Ion beam milling can be performed in the same processing chamber by establishing a suitable vacuum.

### Terminology

As used herein, high vacuum or high vacuum pressure (HV or HV pressure) denotes a chamber pressure of less than 0.1 Pa, and typically much less such as 0.05 Pa, 0.01 Pa, 0.001 Pa, or less. At HV pressures, mean free path (MFP) is generally sufficiently long so that contamination produced at a workpiece can propagate to surfaces throughout a vacuum chamber. For example, at 0.01 Pa, MFP of nitrogen is on the order of about 50 mm. For other pressures and materials, MFP can be estimated as inversely proportional to pressure, proportional to temperature, and inversely proportional to a square of molecular diameter. Low vacuum or low vacuum pressure (LV or LV pressure) refers to pressures greater than 2 Pa, 5 Pa, 10 Pa, 100 Pa, 1 kPa, or more. MFP of nitrogen at 2 Pa is on the order of about 2 mm; at typically used LV pressures, MFPs can be sufficiently small so that contamination from milling or other processes does not reach chamber walls and components. Typically, only shutters placed proximate an objective lens used in workpiece imaging and the workpiece surface are within a few MFPs of any contamination that is produced.

As used herein, a CPB optical column comprises a combination of CPB optical elements such as CPB lenses, deflectors, and/or stigmators used to focus a CPB beam for imaging or workpiece processing. An objective lens of a CPB optical column refers to the optical element closest to a workpiece that is to be imaged or processed using the CPB optical column. The optical elements of a CPB column are generally aligned along an axis.

A pump rate or a pump speed associated with production and maintenance of vacuum refers to a rate at which chamber pressure can be reduced. Pump rates and pump speeds are conveniently noted as volume/time. Variations in pump rate/speed can be accomplished with control of a pump or varying connection of a pump to a chamber such as by control of a valve that couples the pump to the chamber. As used herein, valves are selectively operable to adjust flow rates and evacuation and typically provide adjustable control between fully open and fully closed states.

A flow tube or gas inlet refers to a device that can direct a gas flow to a workpiece. While referred to as a tube, a cross-section of such as device can be polygonal, ellipsoidal, or other shape and is not limited to circular cross-sections. Ends of such flow tubes can be configured as nozzles but this is generally unnecessary. A suction tube or gas outlet refers to a device that capture portions of gas flows and debris from a workpiece and direct them away from surfaces of and within a vacuum chamber. Flow and suction can be arranged to be incident to/from workpieces at arbitrary angles although in some cases, residual contamination can be more apparent on workpiece areas on an opposite side of the workpiece from which a gas flow is directed. Chamber pressures can be regulated by introduction of a gas or mixture of gases such as nitrogen, carbon dioxide, a noble gas such as argon, xenon, or other noble gases, or other non-reactive gas. In other examples, a gas that is reactive with contaminants is used to further reduce redeposition. These gases and mixtures can also be used for directed gas flow to a workpiece. Nitrogen is commonly available in processing systems and is convenient.

In the examples, workpieces are processed at one or more chamber pressures and imaged at a suitable pressure for SEM operation which can also be used for workpiece processing. Workpiece processing at LV pressures is referred to in some examples as “coarse” or “rapid” processing (e.g., milling or ablation) as LV pressures while processing a HV pressures is referred to as fine processing due to the superior edges produced at HV pressures. Workpieces are processed and imaged in a single chamber whose pressure is varied for processing. This approach, referred to herein as “in situ” processing, avoids the need to transport and align the workpiece for imaging and processing in different chambers.

### Example 1

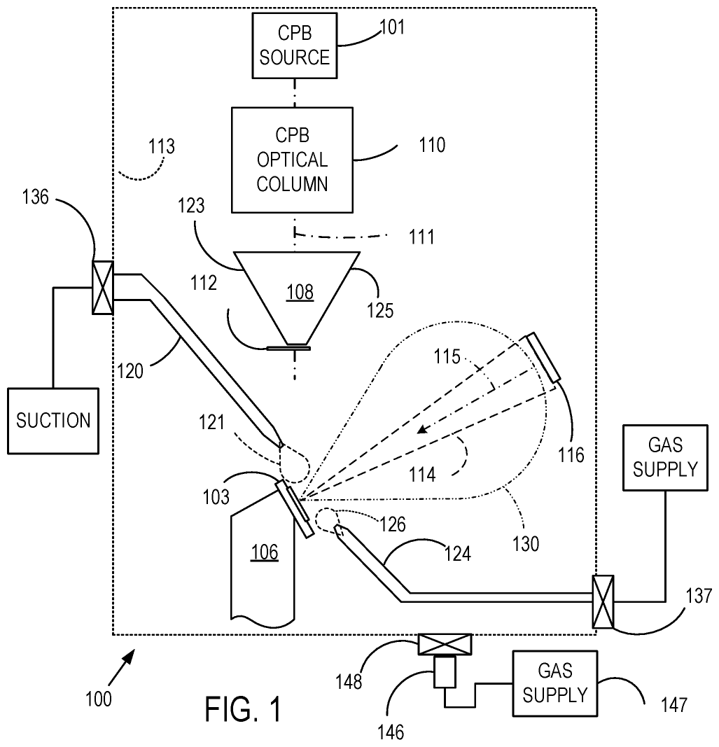

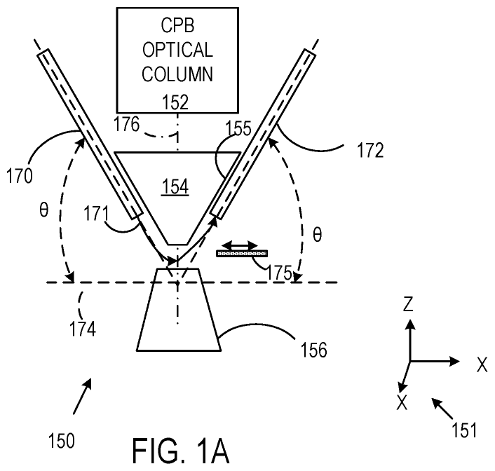

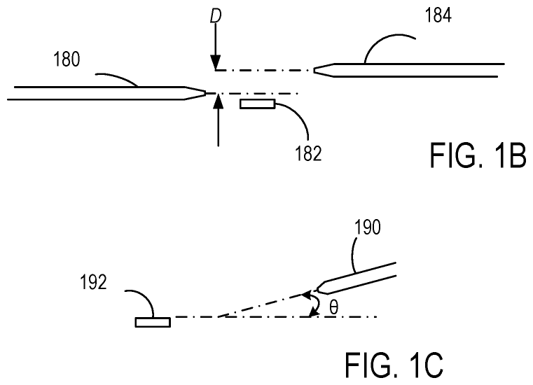

Referring to FIG. 1, a portion 100 of a charged-particle beam (CPB) system such as a scanning electron microscope (SEM) is configured to provide laser-induced ablation at workpieces such as workpiece 103 situated on a workpiece mounting post 106 that is situated in a vacuum chamber 113. The CPB system includes a CPB source 101, an objective lens 108, and additional CPB optics 110, referred to herein as a CPB optical column, situated along an axis 111. A shutter 112 is situated between the objective lens 108 and the workpiece 103 and is movable to protect the objective lens 108 from debris and redeposition of materials associated with laser ablation, or in other examples, debris and redeposition of materials associated with ion beam milling such as focused ion beam (FIB) milling.

In FIG. 1, a laser (not shown) is situated to deliver an optical beam 114 along an axis 115 through a window 116 such as glass slide or cover slip to a working area on the workpiece 103. In response to optical beam exposure, a plume 130 of material is generally produced, but in this example, surface contamination associated with the plume 130 is eliminated or reduced. A suction tube 120 is situated to pull materials away from the workpiece 103 as indicated at 121 and a gas delivery tube (“flow tube”) 124 is situated to direct a gas flow such as a nitrogen gas flow toward the workpiece 103 as indicated by a flow region 126. Valves 136, 137 are provided to selectively couple the suction tube 120 and the gas delivery tube 124 to the vacuum chamber 113. The gas flow and the gas suction directions can be oppositely situated along an axis or at an angle to generate a gas flow such as a laminar gas flow over the workpiece 103. Typically, the axis 115 of the optical beam 114 is perpendicular to a workpiece 103 and a laminar flow direction is perpendicular to the laser beam axis 114. In some cases, alignment is selected for superior performance and/or to avoid mechanical obstruction by CPB optics such as the objective lens 108. Other alignments of the workpiece and gas flow and gas suction directions are illustrated in FIGS. 1A-1C as discussed below.

Pressure in the vacuum chamber 113 can be selected based on preferred processing conditions, and the gas delivery tube 124 and the suction tube 120 can be activated as needed. Pressures such as HV or LV can be regulated with a gas from a gas supply 147 that is coupled to the vacuum chamber 113 via a venting valve 148 and a gas regulator 146. To maintain a fixed chamber pressure, a suction rate provided by the suction tube 120 corresponds to the combined flow rates of the gas delivery tube 124 and gas flow provided via the venting valve 148. As shown in this example, the suction tube 120 is aligned substantially parallel to an exterior surface 125 of the CPB objective 108 which can be defined by a shape of a pole piece. In other examples, the gas delivery tube 124 is aligned substantially parallel to a surface 123 of the CPB objective 108, and in other examples both the suction tube 120 and the gas delivery tube are arranged this way. The workpiece 103 is shown in a particular orientation for purposes of illustration but can be oriented at any angle. In FIG. 1, the workpiece 103 can also be processed with a focused ion beam (FIB) produced with an FIB optical column which is not shown.

Referring to FIG. 1A, a representative processing system 150 includes a CPB optical column 152 and objective lens 154 situated for SEM imaging of a workpiece 156. In FIG. 1A, the workpiece 156 is shown as rotated about an X-axis of a coordinate system 151 and extends in a Y-direction, and an optical processing beam such as a laser beam is typically incident to the workpiece at near normal incidence. A flow tube 170 produces a substantially laminar gas flow 171 to a suction tube 172. The flow tube 170 and the suction tube 172 are situated to extend parallel to an exterior of the objective lens 154 which has surfaces at an angle θ with respect to a perpendicular 174 to an axis 176 of the CPB optical column 152. The tubes 170, 172 can be situated at angles within 2, 5, 10 or 20 degrees of θ, and the angles can be the same or different for each tube. The workpiece 156 is shown as tilted for processing but can be tilted to have a working surface perpendicular to the axis 176 for imaging. A shutter 175 can be selectively inserted between the objective lens 154 and the workpiece 156 to shield the objective lens 154 during processing.

Suction tubes and flow tubes such as shown in FIGS. 1-1A can be arranged in other ways as well, although arrangements based on pole piece shape associated with a CPB lens can be convenient. FIG. 1B illustrates a suction tube 180 situated to receive a gas flow from a flow tube 184 that is directed across a workpiece 182 substantially parallel to a workpiece surface. The suction tube 180 is situated opposite and facing the flow tube 184 but in this case is shown as offset a distance D which is preferably less than a few times a workpiece surface size. In some cases, a suction tube, a flow tube, or both are situated at relatively small angles with respect to a workpiece surface. As shown in FIG. 1C, a flow tube 190 is situated at an angle θ with respect to a workpiece surface 192, wherein 0 is less than 15, 10, 5, or 1 degree. However, in other examples, arbitrary angles can be used.

### Example 2

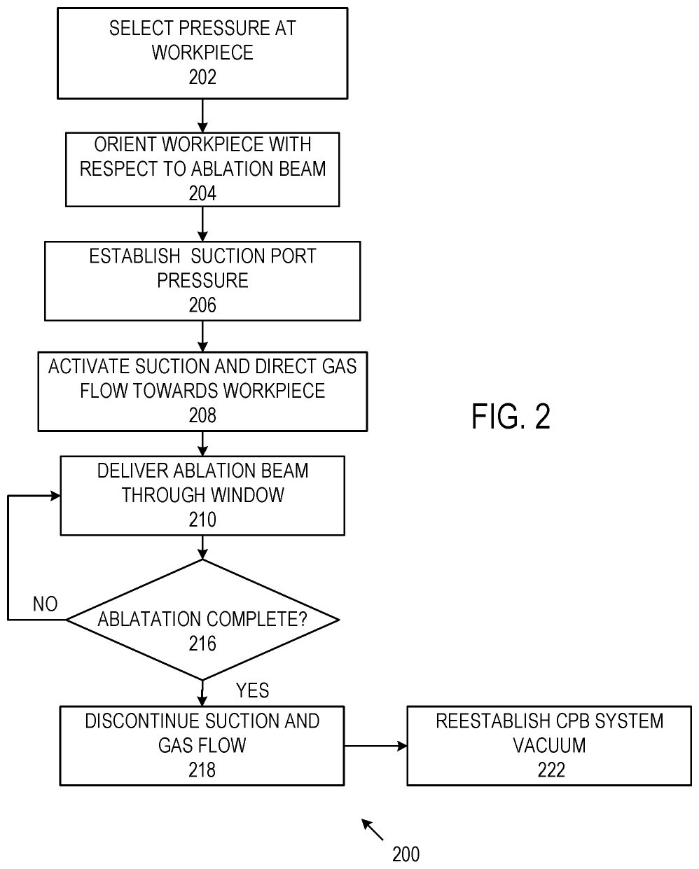

Referring to FIG. 2, a representative method 200 includes selecting a pressure at a workpiece at 202 and orienting the workpiece with respect to an ablation beam at 204. At 206, a suction port pressure is selected, and a gas is directed to the workpiece at 208 from a gas inlet with the suction port activated. The ablation beam is delivered through a window at 210. If ablation is complete as determined at 216, gas flow toward the workpiece and suction are discontinued at 218. At 222, CPB vacuum can be restored to high vacuum such as typically in imaging in SEMs. Otherwise, gas flow and suction continue to be applied during further ablation at 210 until processing is complete.

### Example 3

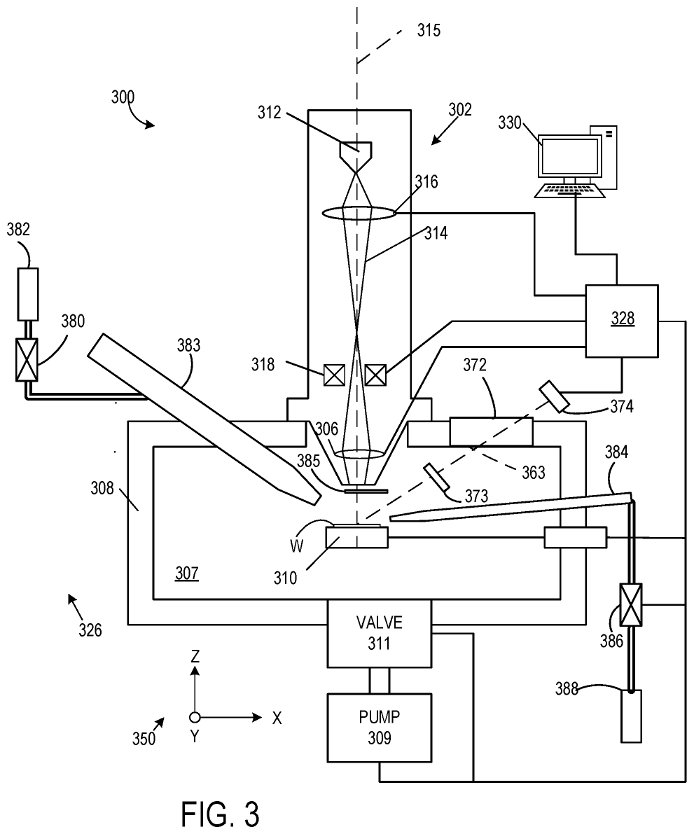

Referring to FIG. 3, in a representative embodiment, a processing system 300 comprises a scanning electron microscope (SEM) 302. An ion beam column can also be provided for ion beam imaging, milling (typically with a FIB and other processing but is not shown in FIG. 3). The SEM 302 can comprise one or more charged particle beam (CPB) lenses such as a condenser lens 316 and an objective lens 306. In some embodiments, one or more CPB lenses can be magnetic lenses, and particularly, the objective lens 306 can be a magnetic objective lens. A workpiece W or other workpiece is secured to a stage 310 that can provide rotations and translations. The SEM 302 is situated for production of an image of the workpiece W. The SEM 302 can be mounted to a vacuum chamber 308 that defines a chamber volume 307 housing the stage 310 and the workpiece W. The vacuum chamber 308 can be evacuated using one or more vacuum pumps 309 that are coupled to the vacuum chamber 308 with a valve 311. The stage 310 can provide movement in the X-Y plane as shown with respect to a coordinate system 350, wherein a Y-axis is perpendicular to a plane of the drawing. The stage 310 can further provide workpiece movement vertically (along a Z-axis) to compensate for variations in the height of the workpiece W. In some embodiments, the SEM 302 can be arranged vertically above the workpiece W and can be used to image the workpiece W. In addition, the stage can be operable to rotate the workpiece W with respect to the axis 315.

The SEM 302 can comprise an electron source 312 and can be configured to manipulate a “raw” radiation beam from the electron source 312 and perform upon operations such as focusing, aberration mitigation, cropping (using an aperture), filtering, etc. The SEM 302 can produce a beam 314 of input charged particles (e.g., an electron beam) that propagates along a particle-optical axis 315. The SEM 302 can generally comprise one or more lenses (e.g., CPB lenses) such as the condenser lens 316 and the objective lens 306 to focus the beam 314 onto the workpiece W. In some embodiments, the SEM 302 can be provided with a deflection unit 318 that can be configured to steer the beam 314. For example, the beam 314 can be steered in a scanning motion (e.g., a raster or vector scan) across a workpiece being investigated. A charged particle detector (not shown) such as an ion or electron detector can be situated to receive charged particles (for example, electrons, ions, secondary electrons) from the workpiece W.

The processing system 300 also includes a laser 374 situated to deliver an optical beam such as a laser beam to the workpiece W along an axis 363 to mill, ablate, or otherwise remove or process the workpiece W. The laser beam can be scanned in a raster pattern or in other ways to apply one or more laser pulses to selected workpiece locations. Beam scanning can be accomplished with electro-optic, acousto-optic or mirror-based scanners (not shown) or by translation of the workpiece W with the stage 310. The laser beam is directed through an optical window 372 in the vacuum chamber 308 and through an internal window 373 such as a cover slip. As discussed above, workpiece processing can result in contamination of the optical windows such as the internal window 373, reducing its transmissivity. While window, detector, and selected other surfaces are particularly sensitive to debris, debris can be widespread absent control measures.

A gas inlet valve 380 is situated to variably regulate introduction of a gas or gas mixture from a gas source 382 (typically a gas cylinder) into the chamber volume 307 via a flow tube 383. As shown, the gas is directed toward the workpiece W. In addition, a gas outlet (suction tube) 384 can be situated to extract at least some of the introduced gas and contamination from the workpiece W to reduce redeposition on the workpiece W and other locations. The gas inlet 384 can be made of a suitable tubing and be coupled into the vacuum chamber 307 with one or more vacuum fittings (not shown) and via a valve 386 to a vacuum pump 388. The suction tube 384 is situated to have an end situated proximate the workpiece W to remove ablated or other materials resulting from laser or ion beam processing of the workpiece W. The system 300 also includes a shutter 385 that is operable to block debris from the workpiece W during processing.

The processing system 300 can further comprise a computer processing apparatus and/or a control unit 328 for controlling inter alia the deflection unit 318, charged particle beam (CPB) lenses 306, 316, and detectors and for displaying information gathered from the detectors on a display unit. The control unit 328 can also control an ion beam to mill or otherwise remove material from selected areas of the workpiece W in addition to or instead of a laser. In some cases, a control computer 330 is provided to establish various excitations, control FIB milling, laser exposures, align the workpiece W before or after ion beam milling or laser operations, record imaging data, control the laser optical system and the laser, control gas flows and suction including valves, vacuum pumps, and generally control operation of the SEM 302 and the laser 374.

In typical examples, the laser 374 is used to ablate a surface of the workpiece W at a selected chamber pressure. The flow tube 383 and the suction tube 384 can be activated, particularly if the chamber pressure is an LV pressure. The control unit can be used to establish appropriate pressures and flows for either coarse or fine processing.

### Example 4

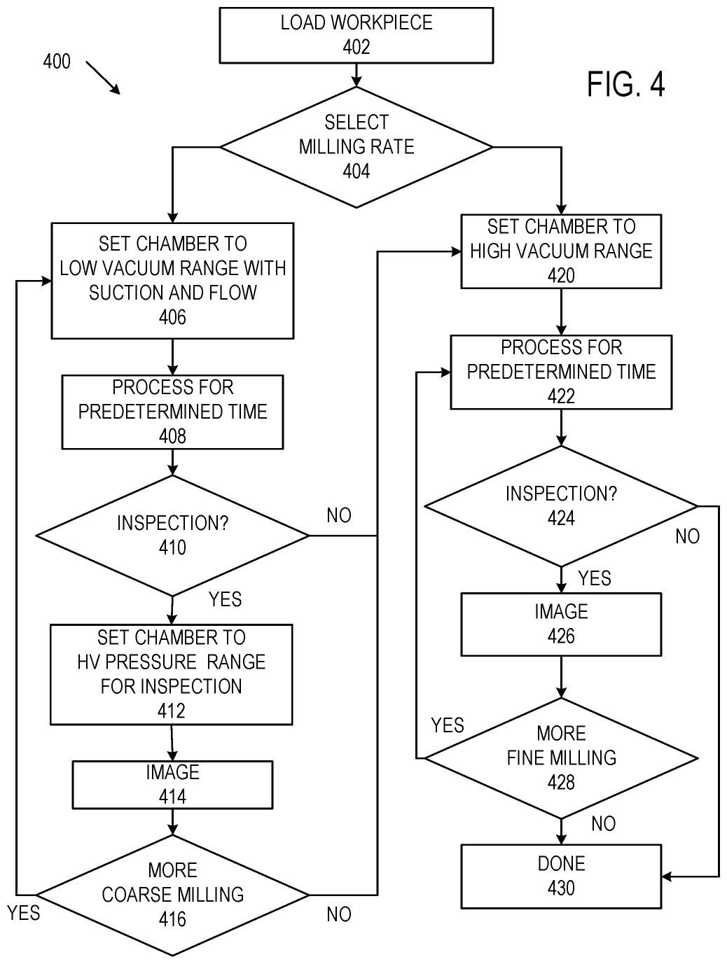

In some cases, processing at LV pressures is used to provide rapid material removal with coarse processing following by fine processing at HV pressures. With reference to FIG. 4, a representative method 400 includes loading a workpiece into a chamber at 402 and selecting a processing (milling or ablation) rate at 404. For LV (coarse) processing, the chamber is set to an LV pressure and gas flow and suction are activated at 406 for processing for a predetermined time at 408. After processing, it is determined if the workpiece is to be inspected as 410. If so, the chamber is set to an HV pressure suitable for inspection by, for example, SEM and the workpiece is imaged at 414. If additional coarse processing is required as determined at 416, processing returns to 406. If coarse processing is completed, the chamber is set or maintained at an HV pressure at 420 and processed for predetermined time at 422. At 424, the workpiece can be selected for inspection and imaged at 426. At 428, based on the image, processing returns to 422 for additional fine milling or is determined to be completed and processing ends at 430.

### Example 5

The examples above are generally described with reference to chamber pressures. However, in the examples, suitable pressures can be selected so that the mean free path (MFP) of ablated particles or other debris or contaminant is limited to avoid redeposition at distant locations. With pressures selected to provide a short MFP, a suction tube is situated to extract contamination and portions of a directed gas flow from a flow tube situated proximate a working location of a workpiece to which a laser beam is directed for processing. Contamination tends to be drawn into the suction tube directly from the working location to reduce redeposition. In one example, chamber pressure of 10 kPa or greater (such as 13 kPa) is produced in a chamber atmosphere that consists of nitrogen gas.

### Example 6

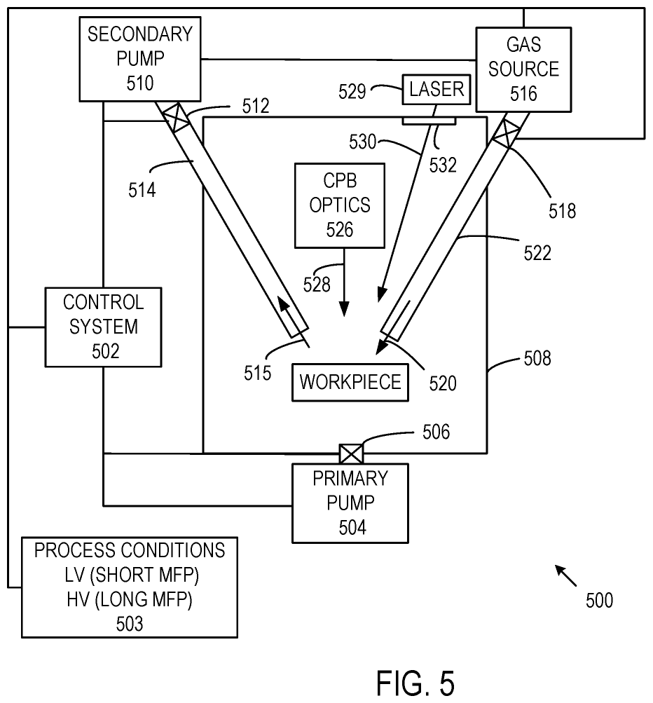

Referring to FIG. 5, a representative processing system 500 that permits contamination control includes a control system 502 (such as a microprocessor system) that is coupled to control a primary pump 504 such as a turbomolecular pump and a valve 506 that couples the primary pump 504 to a vacuum chamber 508. The primary pump 504 is generally selected to produce vacuum required for CPB imaging such as SEM imaging as well as establish HV pressures for workpiece processing. The control system 502 is also coupled to a secondary pump 510 and a valve 512 to control vacuum applied to a suction tube 514 to extract material 515 from the vacuum chamber 508. A gas source 516 is coupled via valve 518 to establish a gas flow 520 from a flow tube 522 toward the workpiece. A CPB optical system 526 is situated to direct a beam 528 to the workpiece and a laser or other optical beam source 529 is situated to direct an optical beam 530 (a processing beam) directed through a window 532 to the workpiece. A non-transitory computer-readable storage device 503 is coupled to the control system 502 and includes processor-executable instructions for establishing processing conditions at a least one LV pressure and one HV pressure by controlling one or more of the primary and secondary pumps 504, 510, valves 506, 512, 518, processing beam sources, CPB microscopy imaging, and other systems and components. An ion beam source and a laser source for production of processing beams are not shown.

### Example 7

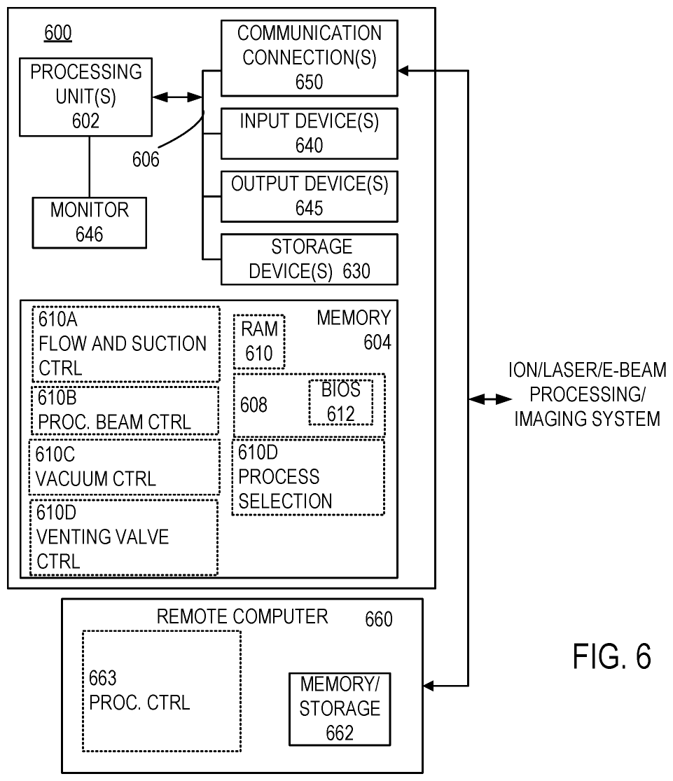

With reference to FIG. 6, an exemplary system for implementing the disclosed technology includes a general-purpose computing device in the form of an exemplary conventional PC 600, including one or more processing units 602, a system memory 604, and a system bus 606 that couples various system components including the system memory 604 to the one or more processing units 602. The system bus 606 may be any of several types of bus structures including a memory bus or memory controller, a peripheral bus, and a local bus using any of a variety of bus architectures. The exemplary system memory 604 includes read only memory (ROM) 608 and random-access memory (RAM) 610. A basic input/output system (BIOS) 612, containing the basic routines that help with the transfer of information between elements within the PC 600, is stored in ROM 608. In the example of FIG. 6, data and processor-executable instructions for controlling directed gas flow and suction tubes are stored in a memory portion 610A. Data and data and processor-executable instructions for processing beam control are optical system control are stored in a memory portion 610B. Data and data and processor-executable instructions for establishing chamber pressures via pump and/or valve control are stored in a memory portion 610C. Control of a venting valve to establish chamber pressure is provide with processor-executable instructions store in a memory portion 610D. Data and data and processor-executable instruction for process selection (e.g., coarse/fine) are stored in a memory portion 610E.

The exemplary PC 600 further includes one or more storage devices 630 such as a hard disk drive for reading from and writing to a hard disk, a magnetic disk drive for reading from or writing to a removable magnetic disk, and an optical disk drive. Such storage devices can be connected to the system bus 606 by a hard disk drive interface, a magnetic disk drive interface, and an optical drive interface, respectively. The drives and their associated computer readable media provide nonvolatile storage of computer-readable instructions, data structures, program modules, and other data for the PC 600.

A number of program modules may be stored in the storage devices 630 including an operating system, one or more application programs, other program modules, and program data. A user may enter commands and information into the PC 600 through one or more input devices 640 such as a keyboard and a pointing device such as a mouse. A monitor 646 or other type of display device is also connected to the system bus 606 via an interface, such as a video adapter. Output devices 645 such as printers can also be provided.

The PC 600 may operate in a networked environment using logical connections to one or more remote computers, such as a remote computer 660. In some examples, one or more network or communication connections 650 are included. The remote computer 660 may be another PC, a server, a router, a network PC, or a peer device or other common network node, and typically includes many or all of the elements described above relative to the PC 600, although only a memory storage device 662 has been illustrated in FIG. 6. The personal computer 600 and/or the remote computer 660 can be connected to a logical a local area network (LAN) and a wide area network (WAN). As shown in FIG. 6, the remote computer 660 includes the memory storage device 662 as well as a memory 663 for data and processor-executable instructions for workpiece processing, chamber pressure control, operation of directed flow and suction tubes, shutter operation, and workpiece imaging.

While the computing environment is described with reference to a personal computer 600, other programmable devices such as one or more programmable logic devices (PLDs), gate arrays, microprocessors, or application specific integrated circuits (ASICs) can be used.

### Additional Considerations

A vacuum suction tube can be situated at various locations at a convenient position that provides suitable performance. Similarly, position of and flow rate provided by a flow tube can be adjusted. Any residual processing debris can tend to be more noticeable on a workpiece side opposite a direction from which gas flow is applied toward a suction tube. Switching between HV for SEM operation and/or ion milling and LV for milling and ablation with an optical beam such as a laser beam can be achieved by valving to select pressures in portions of a vacuum enclosure. In addition, while a flow tube provides a localized, direct gas flow, a venting valve can be used to introduce a gas throughout a vacuum chamber. In some examples, such between LV and HV operations can require less than 2-3 minutes.

### Representative Implementation Clauses

Clause 1 is a charged particle beam (CPB) apparatus, including: a vacuum chamber defined by a vacuum enclosure; at least one CPB objective lens situated in the vacuum chamber and operable to produce an image of a workpiece or to direct a processing CPB to the workpiece to remove material from or add material to the workpiece with the workpiece situated in the vacuum chamber; and a gas inlet and a gas outlet situated to direct a gas flow to the workpiece and receive a gas flow from the workpiece, respectively.

Clause 2 includes the subject matter of Clause 1, and further specifies that the at least one CPB objective lens is situated to produce an image of the workpiece and to direct the processing CPB to the workpiece to remove material from or add material to the workpiece.

Clause 3 includes the subject matter of any of Clauses 1-2, and further specifies that the at least one CPB objective lens includes a first CPB lens situated to produce an image of the workpiece and a second CPB lens situated to direct the processing CPB the workpiece to remove material from or add material to the workpiece.

Clause 4 includes the subject matter of any of Clauses 1-3, and further specifies that the first CPB produces the image of the workpiece in response to an electron beam and the processing CPB directed to the workpiece by the second CPB lens is an ion beam.

Clause 5 includes the subject matter of any of Clauses 1-5, and further includes an optical system situated to direct a processing optical beam to the workpiece as situated in the vacuum chamber to remove material from or add material to the workpiece.

Clause 6 includes the subject matter of any of Clauses 1-5, and further specifies that the optical system includes at least one lens situated to produce an image of the workpiece as situated in the vacuum chamber.

Clause 7 includes the subject matter of any of Clauses 1-6, and further specifies that the optical system includes an optical element situated in an optical beam path to the workpiece, the optical element having at least one surface situated to be exposed to an interior of the vacuum chamber.

Clause 8 includes the subject matter of any of Clauses 1-7, and further specifies that the optical element is an optical window or a lens.

Clause 9 includes the subject matter of any of Clauses 1-8, and further includes a shutter situated between the at least one CPB objective lens and the workpiece, and operable to shield the CPB objective lens from contamination produced at the workpiece in response to processing.

Clause 10 includes the subject matter of any of Clauses 1-9, and further specifies that the gas inlet and the gas outlet are coupled to an inlet valve and an outlet valve, respectively, and further includes a controller coupled to variably regulate at least one of the inlet valve and the outlet valve.

Clause 11 includes the subject matter of any of Clauses 1-10, and further includes a venting valve, wherein the controller is operable to establish a pressure in the vacuum enclosure by controlling the venting valve.

Clause 12 includes the subject matter of any of Clauses 1-11, and further specifies that the controller is operable to establish a low vacuum pressure in the vacuum enclosure by actuating a venting valve to admit a background gas and actuate the inlet valve to direct the gas flow to the workpiece via the gas inlet and actuate the outlet valve to establish the gas flow from gas inlet to gas outlet above the workpiece.

Clause 13 includes the subject matter of any of Clauses 1-12, and further specifies that the controller is operable to establish a high vacuum pressure in the vacuum enclosure by actuating a venting valve, actuating the inlet valve to terminate the gas flow to the workpiece via the gas inlet, and actuating the outlet valve to terminate the receiving of the gas flow from the workpiece.

Clause 14 is a method, including: situating a workpiece in a vacuum chamber at a first pressure; exposing the workpiece as situated in the vacuum chamber at the first pressure to a first processing beam; and during the exposing the workpiece at the first pressure, directing a gas flow to a workpiece surface and withdrawing a gas flow from the workpiece.

Clause 15 includes the subject matter of Clause 14, and further specifies that the first pressure is a low vacuum pressure.

Clause 16 includes the subject matter of any of Clauses 14-15, and further specifies that the gas flow consists essentially of one or more of nitrogen, oxygen, a noble gas, an organic gas, a carrier gas, a halogen-containing gas, and carbon dioxide. Any gases might be introduced and different mixing methods can be used.

Clause 17 includes the subject matter of any of Clauses 14-16, and further includes, after the exposing at the first pressure: with the workpiece situated in the vacuum chamber, establishing a second pressure in the vacuum chamber and discontinuing the directing a gas flow to the workpiece surface and the withdrawing the gas flow from the workpiece; and exposing the workpiece in the vacuum chamber to second processing beam.

Clause 18 includes the subject matter of any of Clauses 14-17, and further specifies that the second pressure is a high vacuum pressure.

Clause 19 includes the subject matter of any of Clauses 14-18, and further specifies that the first processing beam is an optical beam operating to produce a first processing rate, and the second processing beam is the optical beam operating to produce a second processing rate, wherein the first processing rate is greater than the second processing rate.

Clause 20 includes the subject matter of any of Clauses 14-19, and further specifies that the first processing beam and the second processing beam are produced by a common optical beam source.

Clause 21 includes the subject matter of any of Clauses 1-21, and further specifies that the first processing beam and the second processing beam is a laser beam.

Clause 22 is a method of processing a workpiece, including: processing a workpiece at a first rate in a vacuum chamber in a low vacuum environment while directing a gas flow to the workpiece and suctioning debris from the workpiece; processing the workpiece in the vacuum chamber at a second rate in a high vacuum environment without directing a gas flow to the workpiece and suctioning debris from the workpiece, wherein the first rate is associated with greater production of debris or surface contamination than the second rate; and after the processing, imaging the workpiece in the vacuum chamber.

In view of the many possible embodiments to which the principles of the disclosed technology may be applied, it should be recognized that the illustrated embodiments are only preferred examples and should not be taken as limiting the scope of the disclosure.

We claim:

1. A charged particle beam (CPB) apparatus, comprising:
a vacuum chamber defined by a vacuum enclosure;
at least one CPB objective lens situated in the vacuum chamber and operable to produce an image of a workpiece or to direct a processing CPB to the workpiece to remove material from or add material to the workpiece with the workpiece situated in the vacuum chamber; and
a gas inlet and a gas outlet situated to direct a gas flow to the workpiece and receive a gas flow from the workpiece, respectively.

2. The CPB apparatus of claim 1, wherein the at least one CPB objective lens is situated to produce an image of the workpiece and to direct the processing CPB to the workpiece to remove material from or add material to the workpiece.

3. The CPB apparatus of claim 1, wherein the at least one CPB objective lens includes a first CPB lens situated to produce an image of the workpiece and a second CPB lens situated to direct the processing CPB the workpiece to remove material from or add material to the workpiece.

4. The CPB apparatus of claim 3, wherein the first CPB produces the image of the workpiece in response to an electron beam and the processing CPB directed to the workpiece by the second CPB lens is an ion beam.

5. The CPB apparatus of claim 1, further comprising an optical system situated to direct a processing optical beam to the workpiece as situated in the vacuum chamber to remove material from or add material to the workpiece.

6. The CPB apparatus of claim 5, wherein the optical system includes at least one lens situated to produce an image of the workpiece as situated in the vacuum chamber.

7. The CPB apparatus of claim 5, wherein the optical system includes an optical element situated in an optical beam path to the workpiece, the optical element having at least one surface situated to be exposed to an interior of the vacuum chamber.

8. The CPB apparatus of claim 7, wherein the optical element is an optical window or a lens.

9. The CPB apparatus of claim 1, further comprising a shutter situated between the at least one CPB objective lens and the workpiece, and operable to shield the CPB objective lens from contamination produced at the workpiece in response to processing.

10. The CPB apparatus of claim 9, wherein the gas inlet and the gas outlet are coupled to an inlet valve and an outlet valve, respectively, and further comprising a controller coupled to variably regulate at least one of the inlet valve and the outlet valve.

11. The CPB apparatus of claim 10, further comprising a venting valve, wherein the controller is operable to establish a pressure in the vacuum enclosure by controlling the venting valve.

12. The CPB apparatus of claim 10, wherein the controller is operable to establish a low vacuum pressure in the vacuum enclosure by actuating a venting valve to admit a background gas, actuating the inlet valve to direct the gas flow to the workpiece via the gas inlet, and actuating the outlet valve to establish the gas flow from gas inlet to gas outlet above the workpiece.

13. The CPB apparatus of claim 10, wherein the controller is operable to establish a high vacuum pressure in the vacuum enclosure by actuating of a venting valve and actuate the inlet valve to terminate the gas flow to the workpiece via the gas inlet and actuate the outlet valve to terminate the receiving of the gas flow from the workpiece.

14. A method, comprising:
situating a workpiece in a vacuum chamber at a first pressure;
exposing the workpiece as situated in the vacuum chamber at the first pressure to a first processing beam; and
during the exposing the workpiece at the first pressure, directing a gas flow to a workpiece surface and withdrawing a gas flow from the workpiece.

15. The method of claim 14, wherein the first pressure is a low vacuum pressure.

16. The method of claim 14, wherein the gas flow consists essentially of one or more of nitrogen, oxygen, a noble gas, an organic gas, a carrier gas, a halogen-containing gas, and carbon dioxide. Any gases might be introduced and different mixing methods can be used.

17. The method of claim 14, further comprising, after the exposing at the first pressure:
with the workpiece situated in the vacuum chamber, establishing a second pressure in the vacuum chamber and discontinuing the directing a gas flow to the workpiece surface and the withdrawing the gas flow from the workpiece; and
exposing the workpiece in the vacuum chamber to second processing beam.

18. The method of claim 17, wherein the second pressure is a high vacuum pressure.

19. The method of claim 17, wherein the first processing beam is an optical beam operating to produce a first processing rate, and the second processing beam is the optical beam operating to produce a second processing rate, wherein the first processing rate is greater than the second processing rate.

20. The method of claim 19, wherein the first processing beam and the second processing beam are produced by a common optical beam source.

21. The method of claim 19, wherein the first processing beam and the second processing beam is a laser beam.

22. A method of processing a workpiece, comprising:
processing the workpiece at a first rate in a vacuum chamber in a low vacuum environment while directing a gas flow to the workpiece and suctioning debris from the workpiece;
processing the workpiece in the vacuum chamber at a second rate in a high vacuum environment without directing a gas flow to the workpiece and suctioning debris from the workpiece, wherein the first rate is associated with greater production of debris or surface contamination than the second rate; and
after the processing, imaging the workpiece in the vacuum chamber.
